(19) United States
(12) Patent Application Publication
(10) Pub. No.: US 2006/0185595 A1
(43) Pub. Date: Aug. 24, 2006

(54) Apparatus and process for carbon nanotube growth

(76) Inventors: Bernard F. Coll, Fountain Hills, AZ (US); Scott V. Johnson, Scottsdale, AZ (US)

Correspondence Address: INGRASSIA FISHER & LORENZ, P.C., 7150 E. CAMELBACK, STE. 325, SCOTTSDALE, AZ, 85251, US

(21) Appl. No.: 11/064,653

(22) Filed: Feb. 23, 2005

(51) Int. Cl. C23C 16/00

(52) U.S. Cl. 118/724

(57) ABSTRACT

An apparatus is provided for growing high aspect ratio emitters (26) on a substrate (13). The apparatus comprises a housing (10) defining a chamber and includes a substrate holder (12) attached to the housing and positioned within the chamber for holding a substrate having a surface for growing the high aspect ratio emitters (26) thereon. A heating element (17) is positioned near the substrate and being at least one material selected from the group consisting of carbon, conductive cermets, and conductive ceramics. The housing defines an opening (15) into the chamber for receiving a gas into the chamber for forming the high aspect ratio emitters (26).

### FIELD OF THE INVENTION

The present invention generally relates to an apparatus and process for selective manufacturing of high aspect emitters and more particularly to an apparatus and process for manufacturing carbon nanotubes over a large surface area.

### BACKGROUND OF THE INVENTION

Carbon is one of the most important known elements and can be combined with oxygen, hydrogen, nitrogen and the like. Carbon has four known unique crystalline structures including diamond, graphite, fullerene and carbon nanotubes. In particular, carbon nanotubes refer to a helical tubular structure grown with a single wall or multi-wall, and commonly referred to as single-walled nanotubes (SWNTs), or multi-walled nanotubes (MWNTs), respectively. These types of structures are obtained by rolling a sheet formed of a plurality of hexagons. The sheet is formed by combining each carbon atom thereof with three neighboring carbon atoms to form a helical tube. Carbon nanotubes typically have a diameter in the order of a fraction of a nanometer to a few hundred nanometers.

Existing methods for the production of carbon nanotubes, include arc-discharge and laser ablation techniques. Unfortunately, these methods typically yield bulk materials with tangled nanotubes. Recently, reported by J. Kong, A. M. Cassell, and H Dai, in Chem. Phys. Lett. 292, 567 (1988) and J. Hafner, M. Bronikowski, B. Azamian, P. Nikoleav, D. Colbert, K. Smith, and R. Smalley, in Chem. Phys Lett. 296, 195 (1998) was the formation of high quality individual single-walled carbon nanotubes (SWNTs) demonstrated via thermal chemical vapor deposition (CVD) approach, using Fe/Mo or Fe nanoparticles as a catalyst. The CVD process has allowed selective growth of individual SWNTs, and simplified the process for making SWNT based devices. The selection of the desired production process should consider carbon nanotube purity, growth uniformity, and structural control. Arc-discharge and laser techniques do not provide the high purity and limited defectivity that may be obtained by the CVD process. The arc-discharge and laser ablation techniques are not direct growth methods, but require purification, placement and post treatment of the grown carbon nanotube. In contrast to the conventional plasma-enhanced CVD (PECVD) methode, a known hot filament chemical vapor deposition (HF-CVD) technique allows one to prepare high quality carbon nanotubes without damage to the carbon nanotubes structure. Because of the lack of a need for plasma generation, a HF-CVD system apparatus is usually of simple design and low cost. As compared to thermal CVD, HF-CVD demonstrates high carbon nanotube growth rate, high gas utilization efficiency and good process stabilization over large area substrate at relatively low temperature suitable with the glass substrate transformation point (typically between 480° C. to 620° C.).

The hot filaments array is the thermal activation source of the HF-CVD apparatus. Its main functions are to heat the process gas, to dissociate the hydrocarbon precursors into reactive species and fragment molecular hydrogen into active atomic Hydrogen. These active species then diffuse to the heated substrate (typically a glass panel) where catalytic carbon nanotube growth takes place. In prior art HF-CVD systems, the heated surface of thin metal filaments are converted info carbide, or carburizes, in the presence of hydrocarbon gases. The formation of carbides is known to promote filament fragility and consequently filament lifetime issues. Furthermore, the filament brittleness outcome is intensified by the hydrogen that is present in the process gas mixture. Generally the diameter of hot filaments used in conventional HF-CVD processes is small (i.e. on the order of few hundred micro meters to about 1 milimeter) and the filaments are physically supported at their extremities by a rigid grid frame, so that the filaments are stretched in a horizontal direction. During filament resistive heating, due to thermal re-crystallization, these small diameter filaments tend to expand in the linear direction. As a result, the hot and thin filaments tend to physically sag toward the substrate due to gravity; thereby producing deformed filaments and uneven filament grid gap over the planar substrate surface. As the substrate to filament distance is thus distorted by this filament sagging, the non regular shape of the hot filament grid promotes localized temperature variation and consequently growth non uniformity over large substrate area.

Field emission devices that generate electron beams from electron emitters such as carbon nanotubes at an anode plate for creating an image or text on a display screen are well known in the art. The use of a carbon nanotube as an electron emitter has reduced the cost of vacuum devices, including the cost of a field emission display. The reduction in cost of the field emission display has been obtained with the carbon nanotube replacing other electron emitters (e.g., a Spindt tip), which generally have higher fabrication costs as compared to a carbon nanotube based electron emitter. Each of the electron beams are received at a spot on the anode plate, referred to as a pixel on the display screen. The display screen may be small, or very large such as for computers, big screen televisions, or larger devices. However, integration of carbon nanotube field emitters over very large display requires one to address many fabrication and process quality issues that have proven difficult to overcome. These issues include uneven heating of the substrate, limited temperature range of the glass substrate during carbon nanotube growth, poor control of thermal gas dissociation, contamination of the carbon nanotube, and inconsistent process reliability due to the drift of the filament resistivity at process temperature.

As mentioned above, known manufacturing methods of carbon nanotube display devices require a high temperature. These methods typically require a substrate heater and a gas dissociation source made of an array that encompasses a plurality of resistively heated metallic filaments overlying the nanotube growth region. However, for the HF-CVD of carbon nanotubes over larger display panels, equal distribution of heat required for uniform carbon nanotube growth has not been obtained due to the metallic heater filament bending, or sagging, towards the substrate due to gravity. This creates hotter localized areas where the metallic heater filament sags. The resistively heated metallic filament also provides for thermal dissociation of the process gases; however, the variation of the electrical properties of the metallic filament due to resistance drift leads to variation in the gas dissociation, radical species, and consequently in non uniformity and non reproducibility of the carbon nanotube growth process.

Accordingly, it is desirable to provide an apparatus for manufacturing large scale carbon nanotube display devices. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

An apparatus is provided for growing high aspect ratio emitters on a substrate. The apparatus comprises a housing defining a chamber, and a substrate holder attached to the housing and positioned within the chamber for holding a substrate having a surface for growing the high aspect ratio emitters thereon. A heating element is positioned near the substrate and being at least one material selected from the group consisting of carbon, conductive cermets, and conductive ceramics. The housing defines an opening into the chamber for receiving a gas into the chamber for forming the high aspect ratio emitters.

### BRIEF DESCRIPTION OF THE DRAWINGS

The present invention will hereinafter be described in conjunction with the following drawing figures, wherein like numerals denote like elements, and

FIG. 1 is an isometric schematic of a growth chamber in accordance with an embodiment of the present invention;

FIG. 2 is a side schematic view of the growth chamber of FIG. 1;

FIG. 3 is an isometric view of a heater element shown in FIG. 1;

FIG. 4 is a schematic showing the spacing of the heater element shown in FIG. 3;

FIG. 5 is an isometric view of another embodiment of the heater element;

FIG. 6 is an isometric view of yet another embodiment of the heater element;

FIG. 7 is a schematic side view of the substrate and heater element showing direct radiation from the heater element;

FIG. 8 is a schematic side view of another embodiment of the substrate and heater element showing direct radiation from the heater element.

FIG. 9 is a schematic side view of the substrate showing electron movement during growth;

FIG. 10 is a schematic side view of a first biasing scheme in accordance with an embodiment of the present invention;

FIG. 11 is a schematic side view of a second biasing scheme in accordance with an embodiment of the present invention; and

FIG. 12 is a schematic side view of a third biasing scheme in accordance with an embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

A hot filament chemical vapor deposition apparatus is described in detail below that comprises a plurality of heated filaments having a high melting temperature, a non-metal, electric conductiveness, chemical and thermal inertness, and stability to the process gas (e.g., hydrogen and a hydrocarbon gas mixture, or other reactive gases such as O₂, N₂, and NH₃) used for carbon nanotube growth.

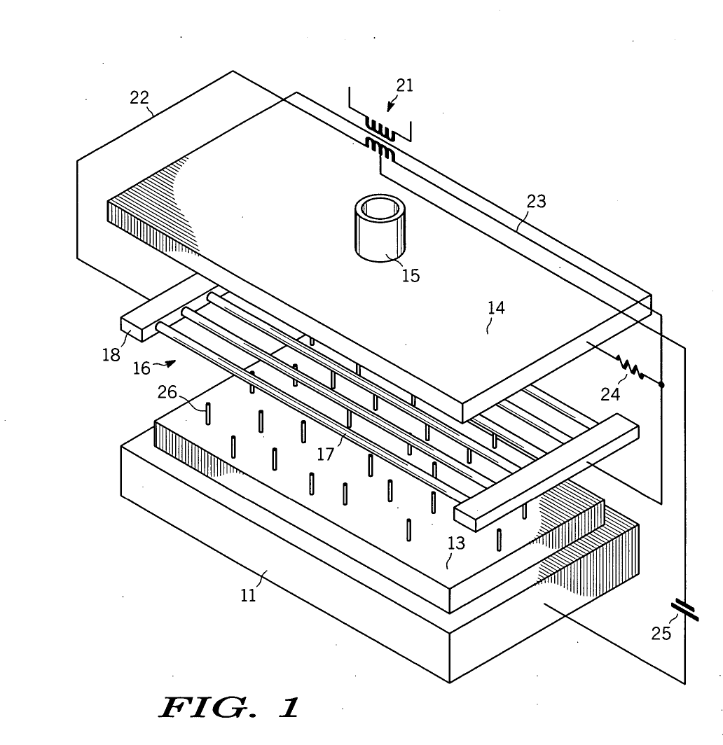

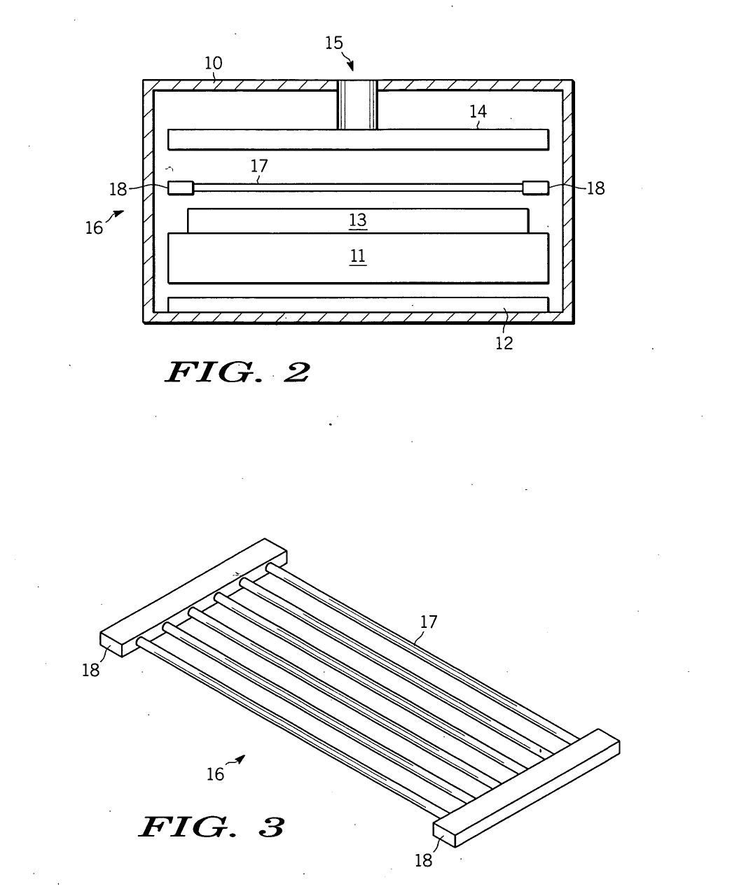

Referring to FIGS. 1 and 2, a simplified schematic view of a growth chamber includes a substrate holder 11 attached to a housing 10. The growth chamber 20 may be used to grow high aspect ratio emitters 26, e.g., carbon nanotubes, on the substrate. A substrate heater 12 is generally positioned below the substrate holder 11 for heating a substrate 13 which is positioned on the substrate holder 11 during growth. Although the substrate heater 12 is typical in most applications (such as the fabrication of integrated circuits), applications are envisioned where it is not required and can be replaced by a water cooled substrate holder (e.g., growth of carbon nanotubes on a low melting point substrate of less than 150° C. such as polymer or plastic). An optional gas showerhead 14 receives reactive feed gas via the gas inlet 15 and is positioned above the hot filament array 17 for distributing gas evenly over the substrate 13. The shower head 14 may not be necessary if the gas transmitted into the chamber 20 is sufficiently pressurized. A substrate for a large glass display is heated by placing it above a substrate heater 12, which typically comprises electrical resistance wire embedded in and electrically insulated from the substrate holder 11 which provides radiative and conductive heat to the substrate holder 11 (a graphite material is the preferred embodiment use for substrate heater to minimize the reactive interaction of the substrate heater element with the reactive gases process). Because the substrate holder 11 has a large thermal mass (compared to the substrate 13), its temperature varies very slowly. This permits better temperature control and uniformity for a large area substrate. The substrate 13 (e.g., glass panels) is placed on the substrate holder 12, and is heated by radiation, conduction, and/or convection. As compared to direct heating by the hot filaments, one of the key advantages of heating with the use of an additional substrate heater is that narrow glass temperature uniformity of the glass panel can be achieved while the water-cooled HF-CVD reactor walls are kept at room temperature. The substrate heater 12 allows better control for adjusting the substrate 13 temperature with the glass substrate in close contact to the substrate heater 12, the temperatures of the two elements are quite close at all times. This offers a practical way to monitor the glass panel average temperature using thermocouples (not shown) embedded in the substrate holder.

In the growth of nanotubes 26, a catalyst (not shown) typically is deposited on the substrate 13 prior to growing the nanotubes 26. The catalyst may comprise Nickel, or any other catalyst made of transition metal known in the industry. Finally to cool the glass panel at the end of the CNT growth process, the glass panel can be removed from the substrate heater and transferred to another load lock chamber (not shown) to speed up the reduction of temperature.

In accordance with the preferred embodiment of the present invention (also referring to FIG. 3), the heating element 16 is a gas dissociation source comprising a plurality of equidistant filaments 17 positioned parallel above the substrate 13. The heating element 16 is coupled between two parallel supports 18 made of conductive material (i.e. metal, graphite, conductive ceramic) and electrically insulated from each other. Each support 18 is connected to a DC voltage source or a low frequency AC voltage source 21 which supply current to resistively heat the filaments 17. When the filaments 17 are heated, the substrate 13 temperature starts to increase up to a certain temperature. This upper limit temperature reached by the substrate 13 is the result of both the amount of heat transfer from the filament 17 and the substrate heater 12, and the heat conductance between the substrate 13 and the substrate holder 11. Therefore, to improve the controllability of the substrate temperature, both the reduction of the heat transfer from the filaments 17 and the increase of the heat conductance are required. A solution to improve the controllability of substrate temperature is to use a carbon mesh-shaped array 41 (FIG. 4) instead of the filaments array 17 (FIG. 3). This mesh shaped array permits a reduction in the amount of heat transfer from the filament and to reduce the difference in temperature between the substrate temperature and the temperature of the substrate holder 11. A bias is provided between the substrate holder 11 and the heating element 16. The parallel filament array 17 is the preferred embodiment for uniform carbon nanotube 26 growth on large substrate area. For a given substrate 13 area and optimized substrate-filament distance, the filament diameter, the minimum filament length, the number of parallel filaments, and the separation between them are considered when designing for efficiency.

The heating element 16 comprises an electrically conducting, high melting temperature material consisting of at least one of carbon (including graphite), conductive cermet, and a conductive ceramics (e.g., B, Si, Ta, Hf, Zr, that form a carbide and/or nitride). According to the preferred embodiment, the filaments 17 are made of straight graphite wires 0.25 mm to 0.5 mm or larger in diameter, and heated by a DC or low frequency AC current. The filaments 17 are arranged to form an array of parallel linear filaments 17 that are parallel to the plane of the substrate 13. They are electrically connected in parallel, each having a length varying from few cm to over 50 cm. must be positioned close enough to the substrate 13 wherein the radiation pattern 61 of each overlap to provide a uniform distribution of heat to the substrate 13. For a given filament diameter, the number of filaments 17 and the distance D between the filaments 17 is determined with respect to an optimum distance H between the filaments 17 and the substrate 13 (see FIG. 4). Generally, to obtain carbon nanotube 26 growth, uniformity apart from ensuring uniform substrate temperature, the filament array 17 is designed in such a way that the distance between the filaments 17 is less than half the distance between the filaments 17 and the substrate 13.

Referring again to FIG. 1, a DC or low frequency AC current source 21 supplies current through connectors 22 and 23 to the supports 18 and thus to the heating element 16 for generating a radiant heat. A resistor 24 is coupled between the gas distribution element 14 and the connector 23 for biasing the gas distribution element 14 so electrons from the heating element 16 are directed away from the gas distribution element 14. A DC voltage source 25 is coupled between the substrate holder 11 and the low frequency AC current source 21, preferably at the center point as shown, for attracting electrons from the heating element 16 towards the substrate 13.

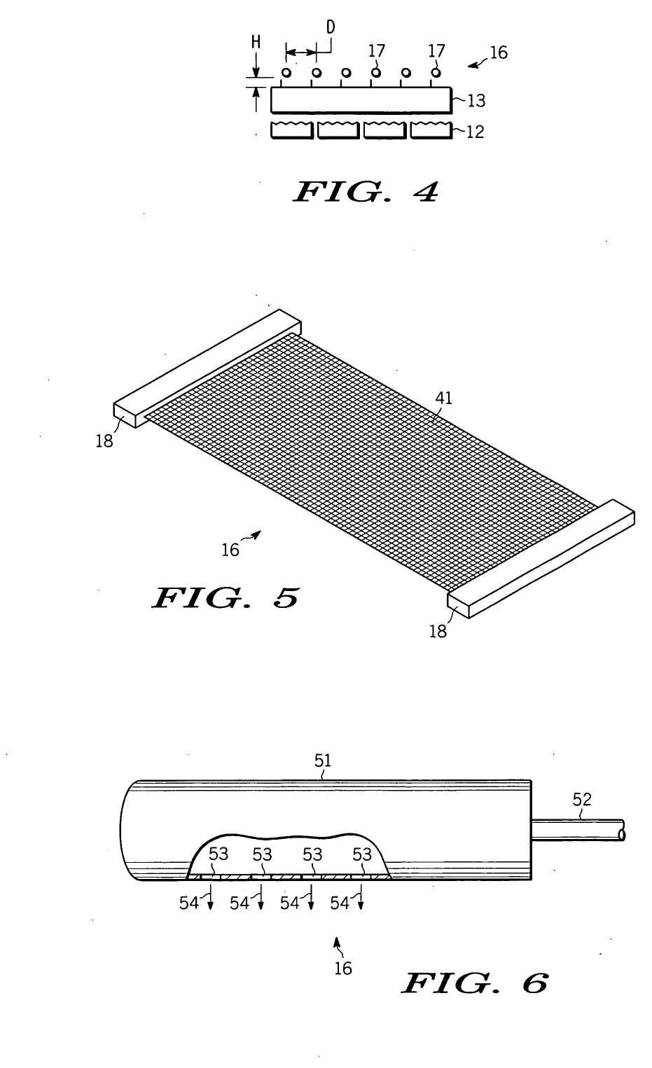

Referring to FIG. 5, a second embodiment of the graphite heating element 16 comprises a mesh 41, positioned between the supports 18. And a third embodiment of the heating element 16, as shown in FIG. 6, comprises a hollow rod acting both as an heating source and a gas distributor 51. The hollow rod 51 comprises an input 52 for receiving process gas and a plurality of orifices 53 for distributing the gas over the substrate 13 as indicated by the arrows 54. As with the first embodiment, the mesh 41 and hollow rod 51 comprise an electrically conducting, high melting temperature material consisting of at least one of carbon (including graphite), conductive cermet, and a conductive ceramics (e.g., B, Si, Ta, Hf, Zr, that form a carbide and/or nitride).

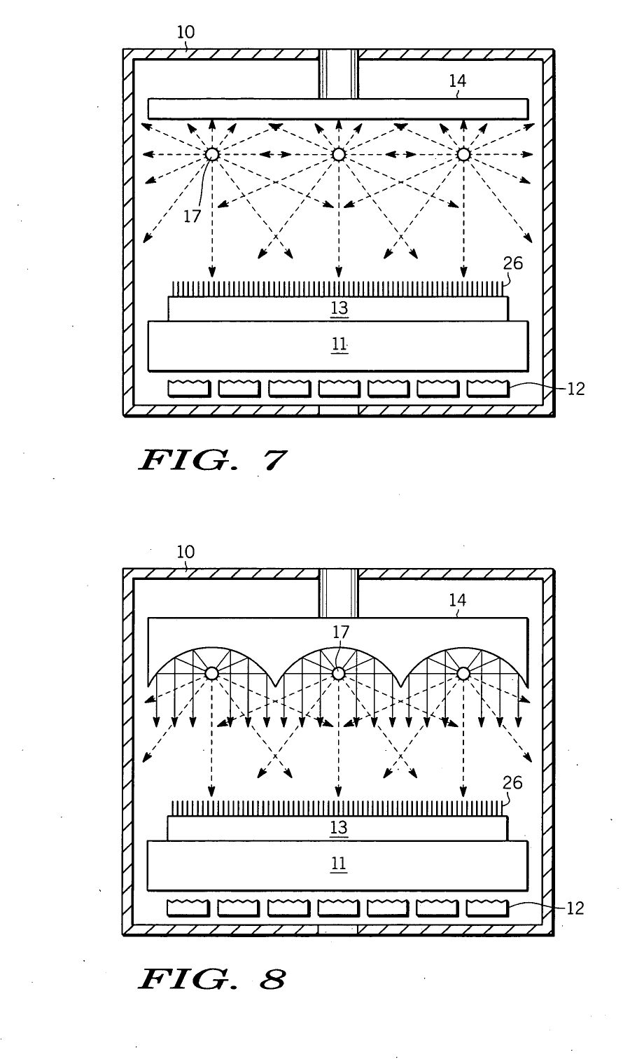

Referring to FIGS. 7 and 8, the filaments 17 radiation is exemplified as two components: one for the direct radiation from the filament 17 and another component for the indirect reflected radiation from the filament, respectively. As expected, approximately half of the radiation power is from direct radiation. The other half is from indirect radiation which is either partially reflected or absorbed by the gas distributor 14 located above the filaments 17. The purpose of the reflector-like gas distributor 14 shape, represented in FIG. 8, is to reflect the radiation from the filament as much as possible downwards towards the substrate 13 and improved radiation uniformity distribution by the showerhead 14 surface facing each filament being shaped more of less like an ellipse. The filament 17 is perfectly centered with respect to this elliptic shape and this elliptic surface is very smooth and preferably coated with highly reflective material.

The substrate 13 is heated by radiation from the heating element 16 and by hydrogen atom recombination. In known CVD processes, a mixture of CH₄ in H₂ flows through the chamber, and a hot filament or plasma is used to dissociate the gas precursors into CH_{y} and H radicals, where y=4, 3, 2, 1, 0. In the HF-CVD method of the preferred embodiment, CH_{y} and H are mainly generated at the surface of the hot filament 17. These species are then transported by diffusion and convection to the substrate. Depending on the catalyst, the carbon nanotube 26 formation consumes the CH_{y} radicals causing their concentrations to decline to the level at which catalytic particle activation and consequently the carbon nanotube growth is reduced or stopped.

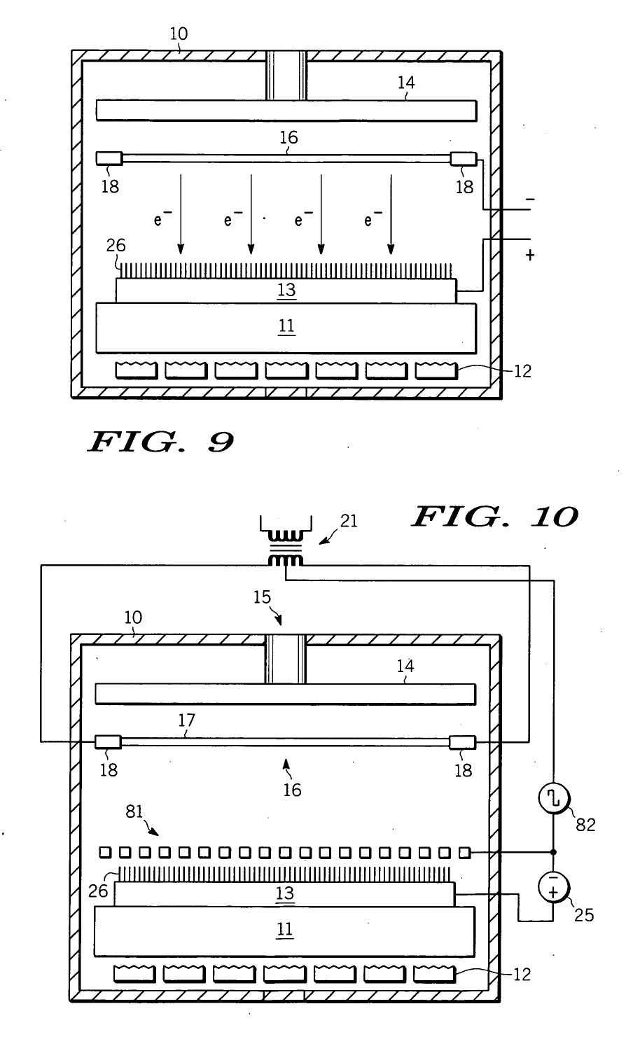

One of the primary functions of the heating element 16 temperature is to set the upper limit of the gas process temperature. The heating element 16 temperature is large enough it produces a thermionic electron emission current whose intensity can be controlled by a positive bias voltage applied to the substrate 13. The electrons interact with the process gases, because there are high densities at the surface of the heated heating element 16. The reaction with CH₄ is well known i.e. e-+CH₄->CH+3+H+2e. even without any acceleration voltage the electrons have an energy of 5 eV. Hence applying a bias increase or decrease the electron energy as shown in FIG. 9. In the absence of a substrate 13 bias, carbon nanotube 26 growth rates are slow. Thus, this thermionic electrons emission enhances the gas molecular fragmentation reactions which form the precursors necessary for the carbon nanotube 26 growth.

The heating element 16 provides several advantages over known systems. First, the non-metalic material used is rigid and does not sag like known metallic filaments. During heating, the metallic filament expansion is a major cause of non-uniform carbon nanotube 26 growth. The known metallic filaments expand when heated to the operating temperatures ranging from 1500° C. to greater than 3000° C. The filament sagging induces hot spots on the glass substrate (where it sags) and relatively cold spots (where it doesn't sag). Therefore, by not sagging, the heating element 16 of the present invention provides a uniform distribution of heat over the substrate 13. The use of carbide or nitride, which has no liquid state, avoids transformation of material characteristics due to temperature change. Secondly, during the carbon nanotube growth, the metallic filaments of the known art typically react with the hydrocarbon gases to form carbide. This carbide formation leads to more thermal-induced stress (more sagging), strong intrinsic resistivity variation and change in the work function. Therefore, one object of this invention is to provide an apparatus where the heated gas dissociation source is made of a non-metallic heating element 16 that is inert to the process reactive gases.

Another advantage of the heating element 16 is an enhanced disassociation of the gas used in the growth process. In accordance with the process of the present invention in the growth of the high aspect emitters 26, e.g., carbon nanotubes, a gas comprising CH₄ and H is applied evenly across the heating element 16 at a temperature preferrably of 1500° C. to greater than 3000° C. and a pressure in the range of 10-100 Torr, cracking the gas, thereby forming various hydrocarbon radicals and hydrogen suitable for the growth process. Referring to FIG. 9, electrons coming out of the hot filaments 17 pass through the vacuum region between the heating element 16 and substrate 13 and hit the substrate, causing a current flow to ground. The heating element 16, being negatively biased to the substrate 13, causes the electrons to accelerate and reach the substrate 13.

One of the key parameters in a HFCVD process is the production rate of atomic hydrogen at the heating element 16. Atomic hydrogen plays a key role in the growth of carbon nanotubes 26 for two reasons: it is crucial in the generation of the hydrocarbon radicals, and it plays an important role in the fragmentation and oxide reduction of catalyst particle as well as in the growth of carbon nanotubes 26. The difference in the characteristics of the synthesized carbon nanotubes 26 in accordance with the present invention is caused by the difference in radical species desorbed from hot surfaces at different heating element 16 temperatures. Radicals generated by the thermal decomposition of hydrocarbon gases (i.e. CH₄) at the hot surface react with gas phase species to produce the precursor molecules for carbon nanotube 26 growth. Control of the gas species desorbed from the heating element 16 is essential for managing of chemical kinetics for the catalytic carbon nanotube 26 growth by HF-CVD processes.

Referring to FIG. 9, electrons are also responsible for the generation of the reactive species which will form the carbon nanotubes 26 upon impact dissociation of the gas molecules, a relevant parameter in the deposition process is the electron current flowing to the substrate 13 in the region between the heating element 16 and the substrate holder 11. If the electric field in this region is sufficient to accelerate the heating element 16 free electrons to energies large enough to produce ionization of the gas molecules, the current collected by the substrate 13 is composed of electrons thermionically generated by the heating element 16 and electrons detached from the gas molecules due to ionization.

As compared to previous art HF-CVD techniques utilizing a metal filament, the electrical resistivity of carbon, a conductive cermet, and conductive ceramics, e.g., B, Si, Ta, Hf, Zr, that form a carbide and/or nitride is greater than the resistivity of pure metal. Thus, the heated heating element 16 can be constructed with a larger diameter. This favors the mechanical strength and rigidity of the heating element 16. It minimizes even more the sagging effect, and improves the lifetime of the heating element 16.

Because graphite heating element 16 do not form carbide (do not carburize), do not melt, and have an extremely high solid to gas phase transition temperature (about 4000° C. for graphite), a broader range of temperatures can be used during the carbon nanotube 26 growth process and contamination of the substrate and subsequently of the carbon nanotubes 26 is less likely to occur. The non-carburization of the heating element 16 is an advantage leading to a reproducible, controllable and uniform carbon nanotube 26 HF-CVD process.

All processes for the carbon nanotube 26 growth by conventional chemical vapor deposition involve the generation of the active species, the transport of the active species to catalyst, and activation of the growth species at the catalyst surface. However, to achieve a high growth rate, more power into the growth system is required to generate more active radicals and deliver them to the surface as fast as possible. A hot heating element 16 is known to be a perfect radiation heat source and a saturated source of electrons as seen in FIG. 9. Thus, the adjunction of negative bias voltage applied to the hot heating element 16 permits the extraction and acceleration of these saturated hot electrons. At a given heating element 16 temperature, electron flow is extracted and controlled by a positive bias 25 applied to the substrate 13. At given pressure, the biased substrate 13 is sufficient to accelerate electrons to energies suitable for fragmentation and excitation of the process gas. Therefore, collision with accelerated electron becomes mainly responsible for gas dissociation and excitation, and permits to operate at lower heating element 16 temperature. This combination of electrical potential and HF-CVD favors a better thermal management between the substrate heater and the heating element 16. It improves the temperature control and permits carbon nanotube 26 growth at lower temperatures. With respect to the heating element 16 temperature and the system pressure (mean free path of the electron) the extraction voltage can be tuned for optimizing the gas phase reaction and the carbon nanotube 26 growth rate. The reason HF-CVD methods can lead to high growth rates are its high working pressure as compared to plasma enhanced CVD (PECVD). In high pressure biased HFCVD, the mean free path for collisions between electrons and molecules is small and thus any excess energy absorbed by the electrons from the applied electric field is quickly redistributed to the larger gas molecules by electron and molecular collisions. Consequently the spacing between the hot heating element 16 and the substrate can be increased for better thermal management and better distribution uniformity of the carbon nanotubes 26. The experimental results show that this combination has advantages in terms of growth rate of carbon nanotube 26 quality for field emission application, over conventional HF-CVD. Therefore, the temperature of the gas molecules and electrons equilibrate at a relatively high temperature. Generation of atomic hydrogen and molecular hydrocarbon radicals occur as the result of both high energy molecular and electron collisions. In addition, the convection and diffusion velocities are increased in this high gas temperature gradient region. Thus, the absolute concentration of atomic hydrogen and molecular radicals is increased in high pressure biased HF-CVD. This contributes to a high carbon nanotube 26 growth rate. In summary, the non-metallic material used for heating element 16 in the HF-CVD process in accordance with the present invention leads to filament 17 extended life time, reduced filament 17 evaporation, and reduced nanotube 26 and substrate 13 contamination, controlled stabilized carbon flux to the substrate 13 during carbon nanotube 26 growth, and reliable and reproducible process from run to run.

Referring to FIG. 10, an intermediate electrode 81 having an alternating current or radio frequency signal 82 applied provides a means for imparting additional energy to the process to create additional disassociation of the gas with the subsequent creation of additional species. During the catalyst induction/or carbon nanotube 26 growth step, the HF CVD reactor could run in this hybrid configuration. First, an additional AC or RF bias voltage 82 is applied between the hot heating element 16 and a plasma-grid placed underneath in the space between the heating element 16 and the substrate 13. Second, a DC or low frequency RF substrate bias 25 could be applied to the substrate 13 to impact its surface with electrons. The function of the AC or RF bias 82 is to generate conventional plasma between the heating element 16 and the intermediate grid 81 leading to gas process dissociation and activation enhancement in this filament-grid confined region. The function of the grid 81 and the DC bias 25 is to shield the effect of ion bombardment at the substrate 13 and to accelerate only the electrons and the reactive hydrocarbon radicals towards the substrate 13. Independent control of the different voltages with respect to the heating element 16 temperature, permits a fine tuning of the gas dissociation and electrons flowing to the substrate 13. In this hybrid mode arrangement, the HF-CVD reactor exhibits higher process flexibility and capability.

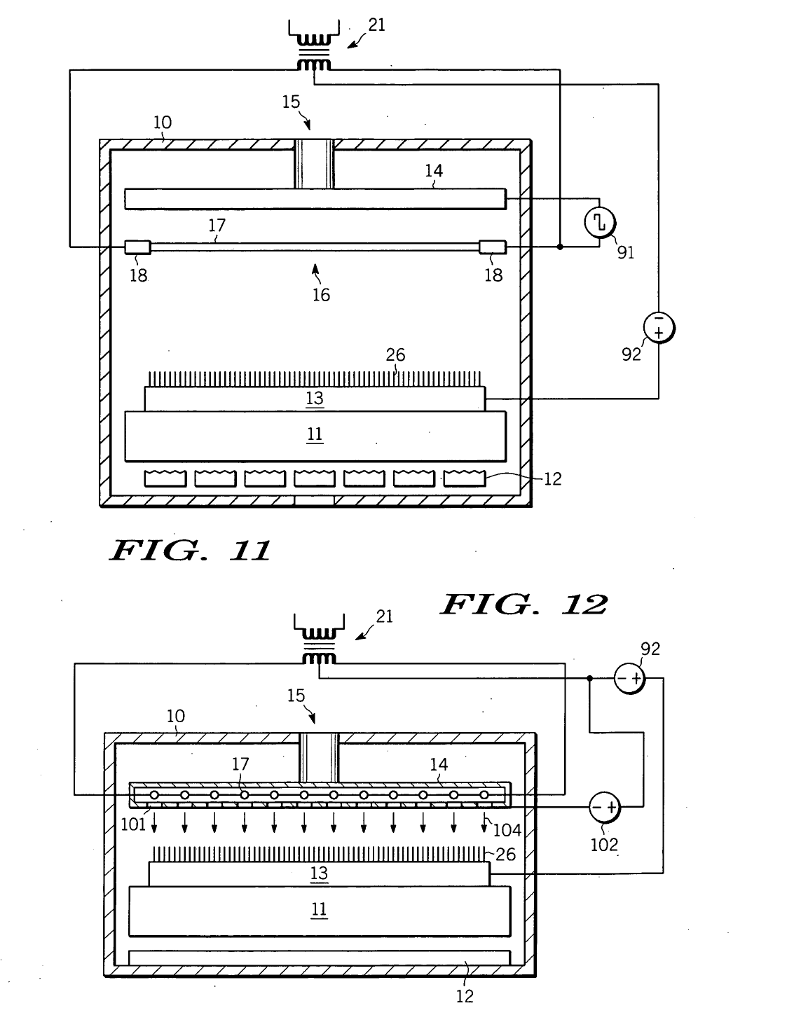

Referring to FIG. 11, an alternating current or radio frequency signal is applied to the heating element 16 and gas showerhead 14, or in absence of showerhead to a thermal shield located over the heating element 16. This arrangement results in additional energy imparted to the precursor gas, causing more efficient disassociation of the gas species. A DC substrate bias is applied to the substrate 13 to extract the saturated electron from the heating element 16 and increase the electron impact of its surface. Both hybrid configuration of HF-CVD allow for independently control of the catalyst induction and carbon nanotube growth stages, to carry out homogenous and uniform carbon nonotube 26 growth, to enhance the substrate 13 bombardment by electrons and shift down the temperature to the range where only selective carbon nanotube 26 growth is still the dominant process. These hybrid HF CVD techniques in comparison to the standard HF CVD technique show significant advantage to control the carbon nanotube 26 growth kinetics over a broader range of substrate 13 materials.

Referring to FIG. 12, yet another embodiment comprises the gas distribution element 14 including openings 101 formed as slits parallel and below the filaments 17 that are positioned within the gas distribution element 14 for distributing the gas as indicated by the arrows 104. The slits (101) are biased with an additional power supply 102 which allows the element to act as a control grid. The addition of this control grid allows the control of the electron flux from the aperture of the slit, while at the same time the material of the gas distributor 14 surrounding the filament 17 rods reduces infrared radiation from the filaments 17, and serves as a gas concentrator to allow more efficient disassociation of the gas species. Controlling the electron flux can be important in the growth and nucleation of certain types of nanotubes and nanowires and can also assist in the nucleation of the nanoparticle.

The heating element 16 consisting of at least one of carbon (including graphite), conductive cermet, and a conductive ceramics (e.g., B, Si, Ta, Hf. Zr, that form a carbide and/or nitride), provides a more uniform distance to substrate 13 with an homogeneous radiation heating of the substrate 13, and a controlled electro-thermal dissociation of the gases which leads to uniform growth of the high aspect ratio emitters 26 over a large area. The high melting temperature of these materials results in a broader range of temperature during emitter growth, a substantial increase in the electron current density flowing out of the heating element 16, and consequently an increase of thermal gas dissociation and the formation of atomic hydrogen. Furthermore, the use of these materials for the heating element 16 eliminates the risk of catalyst and emitter contamination due to evaporation of heating element 16 material (hydrogen embrittlement), provides a constant resistance value of the heating element 16 due to chemical inertness and absence of carbide formation with the heating element 16, and consequently a stable emission current for better gas dissociation reaction from one growth to the next, and longer heating element lifetime. An important consequence of the use of these materials for the heating element 16 is the increase of atomic hydrogen production rate at the heating element 16. The generation of larger flux of electron modulated by an electric field permits more controlled gas dissociation and temperature uniformity, as well as a more mechanically robust and stable thermionic source. These improvements result in a practical reproducible production process and equipment for low temperature growth on a large area substrate.

### Process Example

During a batch HF-CVD process, the HF-CVD reactor is evacuated at a base vacuum pressure in the low 10E-6 Torr by using primary and a turbo-molecular pump package. Once the base pressure in the reactor is reached, the heating element 16, comprising filaments 17 for example, is heated at a temperature preferrably greater than 1500 degree C. The substrate heater 12 is also switched on and allows the substrate 13 temperature to be controlled independently from the filament 17 temperature.

When the substrate 13 reaches a temperature of 350 degree C., molecular high purity hydrogen gas is flowed through a mass flow controller (MFC—not shown) over the hot filament 17. The pressure in the reactor 10 is controlled by adjusting the throttle valve between the deposition chamber (housing 10) and the vacuum pump (not shown), as well as by the MFC. The MFC provides a way to introduce fixed flow rates of process gases into the HF-CVD reactor. The first step of the carbon nanotube growth consists in the catalyst particle fragmentation and reduction in hydrogen at a partial pressure of 1E-1 Torr. The pressure in the HF CVD system is monitored by a MKS pressure manometer (not shown).

When the substrate 13 temperature reaches 500° C., a hydrocarbon gas (e.g., CH₄) is flowed and mixed to the hydrogen gas in very specific hydrogen to hydrocarbon gases ratio, and the power input into the filament array 17 is increased. At the same time the pressure in the reactor is also increased to 10 Torr and then the incubation phase of the catalyst particles (nucleation of carbon nanotubes) is initiated for the time necessary, typically a few minutes, to reach the carbon nanotube growth temperature of 550 degree C.

Once at temperature, the carbon nanotube 26 growth step is started by switching on the DC and/or RF power supply 21 biasing the filaments 17 and the substrate holder 11. Depending on the previous process condition (i.e. pressure, gases ratio, bias current flowing to the substrate) and the carbon nanotubes 26 desired (e.g., length, diameter, distribution, density, etc.), the duration of the growth may vary from 2 minutes to 10 minutes.

At the end of the growth, the filament array 17, the substrate heater 12, as well as the bias voltage 21 are turned off, the process gas flow is switched off and the substrate 13 is cooled down to room temperature. The long cooling down step in batch HF-CVD-reactor 20 can significantly be reduced by flowing a high pressure of neutral gas (e.g., He, Ar) that increases the thermal conduction exchange with the cold wall of the reactor.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. An apparatus for growing high aspect ratio emitters on a substrate, comprising:
a housing defining a chamber;
a substrate holder attached to the housing and positioned within the chamber for holding a substrate having a surface for growing the high aspect ratio emitters thereon;
a heating element positioned within the chamber and near the substrate and being at least one material selected from the group consisting of carbon, conductive cermets, and conductive ceramics; and
wherein the housing defines an opening into the chamber for receiving a gas into the chamber for forming the high aspect ratio emitters.

2. The apparatus of claim 1 further comprising an electrically charged grid positioned between the heating element and the substrate.

3. The apparatus of claim 1 further comprising a gas distribution element coupled to the opening for distributing the gas evenly over the substrate, the heating element positioned within the gas distribution element.

4. The apparatus of claim 1 wherein the heating element comprises a plurality of hollow rods coupled to the opening for distributing the gas evenly over the substrate.

5. The apparatus of claim 1 wherein the heating element comprises a mesh comprising a first plurality of filaments positioned in a first direction and a second plurality of filaments positioned in a second direction.

6. The apparatus of claim 1 wherein the heating element comprises a material that prevents carbide from forming on the heating element.

7. The apparatus of claim 1 further comprising first circuitry for biasing the substrate positive with respect to the heating element.

8. The apparatus of claim 1 wherein the heating element consists of graphite.

9. The apparatus of claim 1 wherein the heating element consists of silicon carbide.

10. The apparatus of claim 1 wherein the heating element comprises a plurality of filaments.

11. The apparatus of claim 1 further comprising a gas distribution element coupled to the opening for distributing the gas evenly over the substrate.

12. The apparatus of claim 11 further comprising second circuitry for biasing the substrate positive with respect to the heating element and the gas distribution element.

13. The apparatus of claim 1 wherein the heating element comprises a material that prevents any carburization of the heating element.

14. The apparatus of claim 13 wherein the heating element comprises a material that generates a saturated thermionic electron emission current.

15. An apparatus for growing high aspect ratio emitters on a substrate, comprising:
a housing defining a chamber having an opening for receiving a gas;
a substrate holder attached to the housing and positioned within the chamber for holding a substrate having a surface for growing the high aspect ratio emitters thereon; and
a heating element positioned within the chamber and near the substrate for providing radiant heating to the substrate and biased for providing a controlled electro-thermal dissociation of the gas.

16. The apparatus of claim 15 wherein the heating element comprises a material that will not change physical or chemical properties in the presence of the gas.

17. The apparatus of claim 15 wherein the heating element is at least one material selected from the group consisting of carbon, conductive cermets, and conductive ceramics.

18. The apparatus of claim 15 further comprising an electrically charged grid positioned between the heating element and the substrate.

19. The apparatus of claim 15 further comprising a gas distribution element coupled to the opening for distributing the gas evenly over the substrate, the heating element positioned within the gas distribution element.

20. The apparatus of claim 15 wherein the heating element comprises a plurality of hollow rods coupled to the opening for distributing the gas evenly over the substrate.

21. The apparatus of claim 15 wherein the heating element comprises a mesh comprising a first plurality of filaments positioned in a first direction and a second plurality of filaments positioned in a second direction.

22. The apparatus of claim 15 wherein the heating element comprises a material that prevents carbide from forming on the heating element.

23. The apparatus of claim 15 wherein the heating element comprises a material that prevents any carburization of the heating element.

24. The apparatus of claim 15 wherein the heating element comprises a material that generates a saturated thermionic electron emission current.

25. The apparatus of claim 15 further comprising first circuitry for biasing the substrate positive with respect to the heating element.

26. The apparatus of claim 25 further comprising second circuitry for biasing the substrate positive with respect to the heating element and the gas distribution element.

27. A method comprising:
providing a substrate having a surface;
providing radiant heat onto the surface from a heating element being at least one material selected from the group consisting of carbon, conductive cermets, and conductive ceramics; and
growing high aspect ratio emitters on the surface.

28. The method of claim 27 wherein the growing step includes distributing a gas evenly over the substrate via a gas distribution element.

29. The method of claim 27 further comprising biasing the substrate positive with respect to the gas distribution element.

30. The apparatus of claim 27 further comprising distributing a gas through the heating element and evenly over the substrate.

31. The apparatus of claim 27 wherein providing radiant heat comprises generating a saturated thermionic electron emission current.

32. The method of claim 27 further comprising biasing the substrate positive with respect to the heating element.

33. The method of claim 27 further comprising second circuitry for biasing the substrate positive with respect to the heating element and the gas distribution element.

34. The method of claim 27 wherein the growing step comprises growing carbon nanotubes.

35. A method comprising:
providing a substrate having a surface;
providing radiant heat onto the surface from a heating element;
biasing the heating element for providing a controlled electro-thermal dissociation of the gas; and
growing high aspect ratio emitters on the surface.

36. The method of claim 35 further comprising biasing the substrate positive with respect to the gas distribution element.

37. The apparatus of claim 35 further comprising distributing the gas through the heating element and evenly over the substrate.

38. The apparatus of claim 35 wherein providing radiant heat comprises generating a saturated thermionic electron emission current.

39. The method of claim 35 further comprising biasing the substrate positive with respect to the heating element.

40. The method of claim 35 wherein the growing step comprises growing carbon nanotubes.

41. An apparatus for growing high aspect ratio emitters on a substrate, comprising:
a housing defining a chamber;
a substrate holder attached to the housing and positioned within the chamber for holding a substrate having a surface for growing the high aspect ratio emitters thereon;
a heating element positioned within the chamber and near the substrate and comprising a material having properties that do not vary due to temperatures below 4000° C.; and
wherein the housing defines an opening into the chamber for receiving a gas into the chamber for forming the high aspect ratio emitters.

42. The apparatus of claim 41 wherein the heating element comprises a material having properties that are inert to the gas.

43. The apparatus of claim 41 wherein the heating element comprises a material that prevents carbide from forming on the heating element.

44. The apparatus of claim 41 wherein the heating element consists of graphite.

45. The apparatus of claim 41 wherein the heating element comprises a material that prevents any carburization of the heating element.

46. The apparatus of claim 45 wherein the heating element comprises a material that generates a saturated thermionic electron emission current.

47. A method comprising:
providing a substrate having a surface;
biasing the substrate positive with respect to a heating element;
providing radiant heat onto the surface from the heating element; and
growing high aspect ratio emitters on the surface.

48. The method of claim 47 further comprising:
controlling electron flow from the heating element to the substrate;
shielding the substrate from thermal radiation emitted from the heating element; and
increasing the gas reaction efficiency.

49. The apparatus of claim 27 wherein providing radiant heat comprises generating a saturated thermionic electron emission current.
